(19) United States
(12) Patent Application Publication
(10) Pub. No.: US 2017/0307666 A1
(43) Pub. Date: Oct. 26, 2017

(54) ADAPTABLE INPUT/OUTPUT APPARATUS AND METHOD

(71) Applicant: General Electric Company, Schenectady, NY (US)

(72) Inventor: Daniel Milton ALLEY, Earlysville, VA (US)

(73) Assignee: General Electric Company, Schenectady, NY (US)

(21) Appl. No.: 15/529,762

(22) PCT Filed: Nov. 25, 2014
(86) PCT No.: PCT/US14/67237

§ 371 Date: May 25, 2017

(51) Int. Cl. G01R 22/10; G01R 22/06

(52) U.S. Cl. CPC G01R 22/10; G01R 22/068; G01R 22/063

(57) ABSTRACT

An integrated circuit and/or sensing circuitry assists in determining the thermal capacity available at a given and future time. In one aspect, the integrated circuit includes a number of channels connected to any number of components having differing thermal capacities. The integrated circuit may provide information relating to available thermal capacity on a per-channel basis as well as on a system-wide basis.

### BACKGROUND OF THE INVENTION

### Field of the Invention

The subject matter disclosed herein generally relates to a programmable integrated circuit that determines available thermal capability.

### Brief Description of the Related Art

A variety of approaches have been used in the creation of input/output (I/O) devices, including the use of I/O modules having components which provide alarms when certain conditions are met. For example, an I/O module may be configured to alert a user when its thermal capacity is exceeded, which may result in an overheating condition. These devices or modules may be modified over time.

In some circumstances, thermal overloads within an I/O module may cause channels or entire modules to go offline which may in turn lead to the loss of control functions. Previous attempts relied upon complicated approaches to monitor thermal conditions. Modules became increasingly large and required larger footprints, which posed difficulties when dealing with limited space. Additionally, multiple modules may be necessary to accommodate the desired number of channels, thereby increasing costs.

The above-mentioned problems have resulted in some user dissatisfaction with previous approaches.

### BRIEF DESCRIPTION OF THE INVENTION

The approaches described herein provide an integrated circuit or other separate sensor circuitry which assists in determining the thermal capacity available at a given and future time. In one aspect, the integrated circuit includes a number of channels connected to any number of components having differing thermal capacities. The integrated circuit or sensor may provide information relating to available thermal capacity on a per-channel basis as well as on a system-wide basis. The use of the adaptable integrated circuit allows the integrated circuit to be operated within safe margins, thus reducing the possibility of failure.

In some approaches, a power consumption monitoring apparatus is provided that includes an interface having an input and an output and a controller coupled to the interface. The controller is configured to determine whether an electric module is capable of supporting a plurality of channels without exceeding a worst-case module thermal behavior value. The controller is further configured to calculate a power margin value that is representative of the remaining power available in the electric module to be used by at least one additional channel. The controller is then configured to transmit a signal to the operator console, update system parameters available to the system's user program or programming tools, and/or adjust the output of the interface indicating the availability of remaining power in the electric module or the lack of power available in the electric module.

In many of these approaches, for each channel of the plurality of channels, the controller is further configured to measure a present operating value, determine a present channel load value using the present operating value, determine a worst-case channel power dissipation value using the present operating value; and determine a worst-case channel thermal behavior value using the present operating value. In additional examples, the controller may further be configured to calculate a sum of the present channel load values using each of the measured present channel load values and calculate a worst-case module power dissipation value using the sum of each of the worst-case channel power dissipation values. The controller may also calculate a worst-case module thermal behavior value using the sum of each of the worst-case thermal behavior values and the difference between the worst-case module thermal behavior value and the sum of the present channel load values.

In other examples, the controller may be configured to determine whether the channel exceeds the worst-case channel thermal behavior value. The controller then is configured to transmit a signal to the output of the interface indicating the channel exceeds the worst-case channel thermal behavior value.

In additional approaches, a method for monitoring power consumption of an electronic module having a plurality of channels is provided. For each channel of a plurality of channels of the electronic module, the method computes channel values by measuring a present operating value, determining a present channel load value using the present operating value, determining a worst-case channel power dissipation value using the present operating value, and determining a worst-case channel thermal behavior value using the present operating value.

The method then calculates a sum of the present channel load values of the plurality of channels using each of the measured present channel load values. Next, the method calculates a worst-case module power dissipation value using the sum of each of the worst-case channel power dissipation values of the plurality of channels and calculates a worst-case module thermal behavior value using the sum of each of the worst-case thermal behavior values of the plurality of channels.

The method then determines whether the electronic module is capable of supporting the plurality of channels without exceeding the worst-case module thermal behavior value and calculates a power margin value using said sum of the present channel load values, the worst-case module power dissipation value, and the worst-case module thermal behavior value. This power margin value is representative of the remaining power available in the electronic module to be used by at least one additional channel.

In some examples, the worst-case module thermal behavior value includes a maximum module temperature value as sensed from the power induced temperature rise above the device's ambient temperature. Further, the present operating value may include at least one of a present output current value, a present internal temperature, a present output voltage, a present driver supply voltage, and a present power dissipation value. The present channel load value may be determined using a channel temperature offset, a driver rise value, and the present power dissipation value. The worst-case channel power dissipation value may be determined by multiplying a maximum current value by the difference between the present driver supply voltage and the present output voltage at the driver's output.

In some forms, at the channel of the electronic module the method may further provide an alert that the channel is not capable of supporting the present channel load and the present operating values in response to determining the worst-case channel thermal behavior value. The method may further provide an alert that the electronic module is not capable of supporting the plurality of channels without exceeding the worst-case module thermal behavior value.

So configured, the I/O module described herein may be incorporated within cabinets having fewer cooling resources. As such, the cabinet may be more efficiently packaged, allowing for a greater number of integrated circuits to be disposed therein. In addition, by being able to identify when cooling is compromised will allow additional fans and cooling apparatuses to be turned on as an anticipatory measure. If the amount of thermal margin is available to the I/O system's controller as a variable, then the cooling system may be under the I/O controller's program control to adjust the amount of cooling based on the estimated power dissipation. Further still, the identification of configurations which may lead to future channel overloads may lead to properly functioning systems which have little to no chance of overheating.

### BRIEF DESCRIPTION OF THE DRAWINGS

For a more complete understanding of the disclosure, reference should be made to the following detailed description and accompanying drawings wherein:

FIG. 1 comprises a block diagram illustrating an exemplary adaptable apparatus according to various embodiments of the present invention;

FIG. 2 comprises a block diagram illustrating an exemplary electronics module which may be utilized in the adaptable apparatus of FIG. 1 according to various embodiments of the present invention; and

FIG. 3 comprises a flow chart illustrating an approach for monitoring power consumption according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION OF THE INVENTION

Approaches are provided that overcome the risk of encountering thermal overload in both an individual channel of and an entire Input/Output (I/O) module implementing desired I/O architectures. In one aspect, the approaches monitor any number of channels connected to any number of components having differing thermal capacities and provide notifications to the user. By utilizing the present approaches, the I/O module may be programmed to alert the user of impending thermal overload on a channel-by-channel basis as well as on an I/O module basis.

In one specific example, a power consumption monitoring apparatus includes an interface having an input and an output and a controller coupled to the interface. The controller is configured to determine whether an electronic module is capable of supporting a plurality of channels without exceeding a worst-case module thermal behavior value. In some forms, the controller is also configured to calculate a power margin value that is representative of the remaining power available in the electric module to be used by at least one additional channel. In some forms, the controller is configured to then transmit a signal to the output of the interface indicating the availability of remaining power in the electric module or alternatively the lack of power available in the electric module.

In some approaches, a method for monitoring power consumption of an electronic module having a plurality of channels is provided. In these approaches, for each channel, channel values are computed which include measuring a present operating value, determining a present channel load value using the present operating value, determining a worst-case channel power dissipation value using the present operating value, and determining a worst-case channel thermal behavior value using the present operating value. The method then calculates a sum of the present channel load values, calculates a worst-case module power dissipation value, and calculates a worst-case module thermal behavior value. The method then determines whether the electronic module is capable of supporting the channels without exceeding the worst-case module thermal behavior value. Next, the method calculates a power margin value representative of the remaining power available in the electronic module to be used by an additional channel or channels.

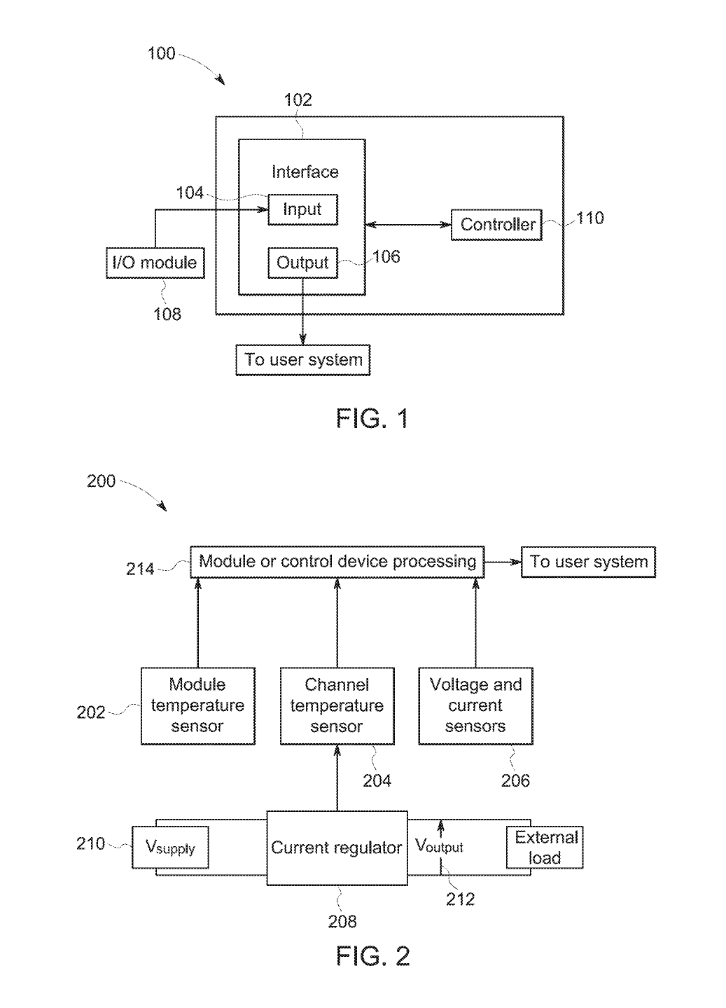

Referring now to FIG. 1, one example of an I/O system 100 is described. The I/O system 100 includes an interface 102 having an input 104 and an output 106, an electric or I/O module 108, and a controller 110. The interface 102 is a computer-based program and/or hardware configured to accept a signal or communication from the I/O module 108 at the input 104 and transmit the generated communication at the output 106 to the user system. Thus, the function of the interface 102 is to allow the controller 110 to communicate with the user system and the I/O module 108.

The controller 110 is any combination of hardware devices and/or software selectively chosen to monitor settings of a desired system and generate, display, and/or transmit communications regarding the system. The controller 110 includes an algorithm that generates the thermal load values and determines whether capacity may be available within the I/O module.

The I/O module 108 may be any combination of hardware devices chosen to monitor, control, and/or cause an action to occur. For example, the I/O module 108 may include any number of channels having components such as switches, valves, actuators, gates, pumps, sensors, gears, systems, and the like. When operating, these components may create energy, and thus require energy to be dissipated to allow the I/O module 108 to function properly. These devices may all be physically coupled to each other through conventional methods such as cables capable of transmitting data, or they may communicate with each other through any number of wireless communications protocols.

It will be appreciated that the various components described herein may be implemented using a general purpose processing device executing computer instructions stored in memory. Further, it is understood that the controller 110 may be a standalone component or may be incorporated into the I/O module 108.

In operation, for each channel of the I/O module 108, the controller 110 first measures present operating values such as the present current, present thermal behaviors such as temperatures for the channel and any components with internal temperature sensors, I/O module 108 driver supply voltages, and present power dissipation values. These values may be measured using any number of devices known to those having skill in the art. For example, current may be measured when a digital-to-analog (D-A) circuit is used in the I/O module 108 which may include switching mechanisms that connect current output to output terminals. Oftentimes, D-A circuits create a voltage that regulates a transistor driver and also includes a feedback circuit which senses the driver current via sensing the emitter voltage. This type of structure is configured to have current flowing out to the output circuit which may then be measured.

The controller 110 then uses the present operating values to perform a number of calculations and estimations. Based on previously known and stored information pertaining to the particular components in each channel, the present operating values of current and resulting output voltage may be used to determine a present channel load. Also, based on the particular componentry used in the I/O module 108, a maximum or worst-case output current may be determined which in turn may be used to estimate the maximum or worst-case channel output voltage at this max current. During the design of the system, the circuitry is analyzed by thermal models to determine the maximum allowed thermal behavior (typically calculated as maximum allowed power based on the device's external or ambient temperature) for each channel. This may vary across channels based on their location within the device and adjacency to heat sinks, device sides, cooling paths and/or other components. This data includes maximum component temperatures allowed for operation (as specified by the component manufacturer, typically 125 degrees C. for semiconductors) and thermal impedances for the circuit sections (as derived from data for testing the device to cause temperature rises based on dissipated watts yielding parameters with units of degrees C. per watt).

The worst-case channel power dissipation value may be calculated using the supply voltage and the channel output voltage with the maximum current value. This worst-case channel power dissipation value may then be used to determine the worst-case channel thermal behavior (for example, a temperature rise above the device's outside ambient temperature), which takes into account an offset thermal value to include components' quiescent thermal values in addition to the rise in the thermal value for a specified increase in power. If the calculated worst-case channel thermal behavior in a given channel is greater than or equal to the maximum allowed thermal behavior for that channel, the controller 110 is configured to transmit a signal to the output 106 to be sent to the user system to alert the user that the channel will exceed a maximum thermal behavior. Since the maximum current is used for the calculation, while the channel may be using a lower current for a present lower thermal dissipation, a warning may be transmitted as opposed to transmitting a signal that causes the system to be powered off or shut down. These calculations and estimations are then performed on all of the channels present in the I/O module 108.

In the case of a universal I/O module 108, the maximum power per channel for various input types may be known and provided in a table or chart. By summing the power consumed by all channels plus processing power provides the power overhead for the I/O module 108.

The controller 110 may then calculate a sum of the present channel load values using each of the measured present channel load value and calculate a worst-case I/O module power dissipation value using the sum of each of the worst-case channel power dissipation values. A worst-case module thermal behavior value is then calculated, and the difference between the worst-case module thermal behavior value and the sum of the present channel load values of the I/O module 108. If the sum of the present channel load values is greater than or equal to the worst-case module thermal behavior value, a signal may be sent to the output 106 to be sent to the user system to alert the user that the I/O module will exceed a maximum thermal behavior. Conversely, if the sum of the present channel load values is less than the worst-case module thermal behavior value, this indicates that the I/O module may safely support additional channels without exceeding a maximum thermal behavior value. The controller 110 is then configured to transmit a signal to the output 106 to be sent to the user system to alert the user that the I/O module may safely accept additional channels and/or components.

As such, in some approaches, the controller 110 is configured to determine whether the I/O module 108 is capable of supporting a number of channels without exceeding the worst-case module thermal behavior value. The controller 110 is configured to calculate a power margin value which represents the remaining power available in the I/O module 108 to be used by at least one additional channel. The controller 110 is further configured to transmit a signal to the output 106 indicating the availability of remaining power in the I/O module 108 or the lack of power available in the I/O module 108.

Turning to FIG. 2, an exemplary I/O module 200 is provided. The I/O module 200 includes a module temperature sensor 202, a channel temperature sensor 204, voltage and current sensors 206, a current regulator 208, a supply voltage 210, and an output voltage 212 coupled to an external load. As previously mentioned, the I/O module 200 may additional include a module or control device processing unit 214 (which alternatively may be a separate component).

The module temperature sensor 202, channel temperature sensor 204, and voltage and current sensors 206 may be any sensors known and used by those having skill in the art. The current regulator 208 provides the appropriate current output based on the user's system, and is provided with a maximum safe operating current. The current regulator 208 is coupled to the channel temperature sensor 204. The supply voltage 210 and output voltage 212 are power sources provided to the I/O module 200 and the external circuit, respectively. The module or control device processing unit 214 may be any hardware and/or software controls which receive data, process the data, and provide the data to a user system.

In operation and as discussed with regards to FIG. 1, the current regulator 208 provides the appropriate amount of current to the I/O module 200 based on the components being used therein. The channel temperature sensor 204 determines the temperature of the channel based on the current being output and provides this information to the module or control device processing unit 214. The module temperature sensor 202 provides an estimate for the module's outside or ambient temperature. Voltage and current sensors 206 also provide values to the module or control device processing unit 214, which then determines whether each channel as well as the I/O module 200 as a whole has the capacity to accept additional components without overheating. This determination is then sent to the user system, thus allowing the user to either address a potential overheating issue or add additional components to the system as desired.

As an example, a channel of an I/O module may be configured to output currents generally between 4 and 20 mA when operating with a supply voltage of 24 volts into the current regulator for an ambient temperature of between −30 to 70 degrees Celsius. The system measures the present current being output as well as present temperatures and power outputs. Based on known parameters of the individual channel such as the maximum channel output, a maximum channel temperature and power output, for example, 85 degrees Celsius and 0.5 watts, respectively, for safe operation of the channel is determined. At this point, if the present temperature, power output, and currents exceed the maximum allowed values, the system sends an alert which may prompt an operator to modify the particular channel. Similarly, these same values are totaled to provide overall I/O module maximum values. If the system determines additional thermal capacity, power, and/or current may be supported, it will transmit a message indicating this availability and the quantity of the thermal margin, thus allowing a user to add additional channels to the I/O module that remain below this thermal margin. The system may then perform the calculations again to ensure available capacities are not exceeded.

In some forms, the apparatus may be configured to cause any number of cooling techniques to be employed. For example, upon determining values for the present and worst case channel loads, the controller may transmit a signal that causes a fan to be turned on to create additional cooling. Other cooling techniques known to those having skill in the art are envisioned. Conversely, if present operating values are less than maximum allowed values, the controller may be configured to turn off cooling devices that are presently unnecessary.

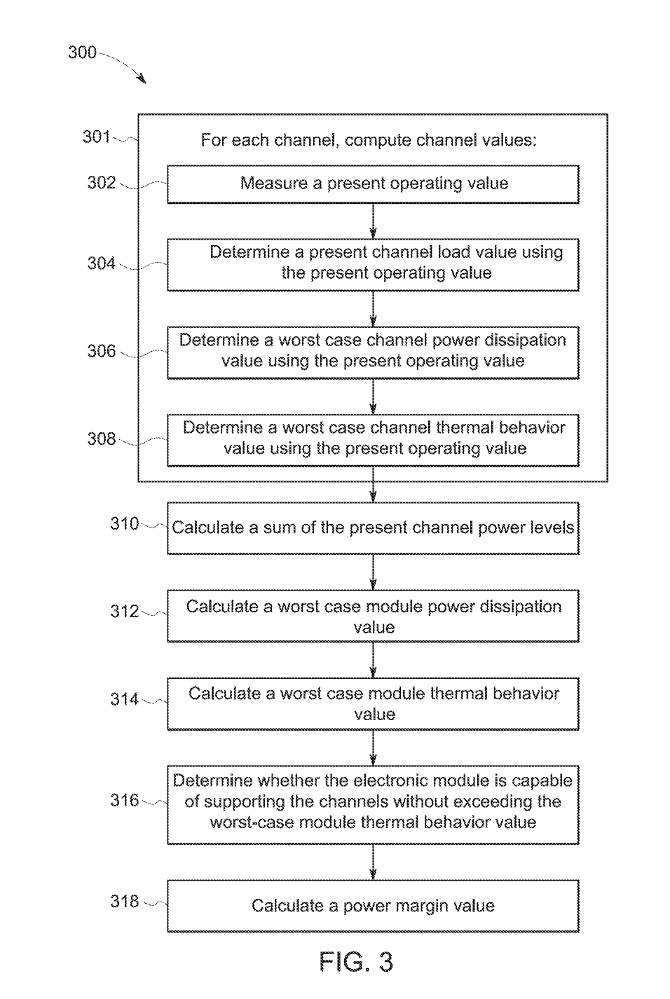

Turning to FIG. 3, an approach for monitoring power consumption of an electronic or I/O module having a number of channels is described. First, at step 301, for each channel of the I/O module, the approach computes channel values. These values include measuring 302 a present operating value, determining 304 a present channel load value using the present operating values for the output voltage divided by the operating current, determining 306 a worst-case channel power dissipation value using the present operating values for supply and output voltages and output current, and determining a worst-case channel thermal behavior value 308 using the present operating value for power dissipation times the predetermined thermal impedance multiplier (units of degrees per watt) added to the present sensed module ambient from the module temperature sensor.

Next, at step 310, the method calculates a sum of the present channel power dissipation levels of each of the plurality of channels using each of the measured present channel load values. At step 312, a worst case module power dissipation value is calculated using the sum of each of the worst-case channel power dissipation values along with the quiescent power for the device. At step 314, a worst case module thermal behavior value is calculated using the sum of each of the worst-case channel thermal behavior values. In some approaches, this worst case module thermal behavior value includes a maximum module temperature value. Next, at step 316, the method determines whether the electronic module is capable of supporting the channels without exceeding the worst case module thermal behavior value. At step 318, a power margin value is calculated using the sum of the present channel load values, the worst case module power dissipation value, and the worst case module thermal behavior value. This power margin is representative of the remaining power available in the I/O module to be used by any number of additional channels.

In some approaches, the step of measuring 302 the present operating value may include measuring any or all of a present output current value, a present internal temperature, a present outside ambient temperature (if sensed at the coolest point in the device), a present output voltage, a present driver supply voltage, and a present power dissipation value. The step of determining 304 the present channel load value may be determined using a channel temperature offset, a channel rise value, and the present power dissipation value.

In some examples, the step of determining 306 the worst case channel power dissipation value is determined by multiplying a maximum current value by the difference between the present driver supply voltage and the present output voltage.

In many of these approaches and, at the channel, in response to determining the worst case channel thermal behavior value, an alert that the channel is not capable of supporting the present channel load and the present operating values is provided. A user may then adjust or modify their system to avoid any potential issues with rising temperatures. In some forms, the method 300 may further include the step of providing an alert that the entire I/O module is not capable of supporting the plurality of channels without exceeding the worst case module thermal behavior value may be provided. As such, the user may be quickly determine whether the I/O module may support additional capacity before adding additional channels thereto.

It will be understood that the functionality of the I/O module may be provided on a single, physical chip or on multiple chips (or other components) disposed at multiple locations. For example, certain components of the I/O module may be disposed with the controller.

It will be appreciated by those skilled in the art that modifications to the foregoing embodiments may be made in various aspects. Other variations clearly would also work, and are within the scope and spirit of the invention. The present invention is set forth with particularity in the appended claims. It is deemed that the spirit and scope of that invention encompasses such modifications and alterations to the embodiments herein as would be apparent to one of ordinary skill in the art and familiar with the teachings of the present application.

What is claimed:

1. A method for monitoring power consumption of an electronic module having a plurality of channels, the method comprising:
for each channel of a plurality of channels of the electronic module, computing a plurality of channel values comprising:
measuring a present operating value,
determining a present channel load value using the present operating value,
determining a worst-case channel power dissipation value using the present operating value,
determining a worst-case channel thermal behavior value using the present operating value;
calculating a sum of the present channel load values of the plurality of channels using each of the measured present channel load values;
calculating a worst-case module power dissipation value using the sum of each of the worst-case channel power dissipation values of the plurality of channels;
calculating a worst-case module thermal behavior value using the sum of each of the worst-case thermal behavior values of the plurality of channels;
determining whether the electronic module is capable of supporting the plurality of channels without exceeding the worst-case module thermal behavior value; and
calculating a power margin value using said sum of the present channel load values, the worst-case module power dissipation value, and the worst-case module thermal behavior value, the power margin value representative of remaining power available in the electronic module to be used by at least one additional channel.

2. The method of claim 1, wherein the worst-case module thermal behavior value comprises a maximum module temperature value.

3. The method of claim 1, wherein the present operating value comprises at least one of a present output current value, a present internal temperature, a present output voltage, a present driver supply voltage, and a present power dissipation value.

4. The method of claim 3, wherein the present channel load value is determined using a channel temperature offset, a driver rise value, and the present power dissipation value.

5. The method of claim 3, wherein the worst-case channel power dissipation value is determined by multiplying a maximum current value by a difference between the present driver supply voltage and the present output voltage.

6. The method of claim 1, further comprising at the channel of the electronic module, in response to determining the worst-case channel thermal behavior value, providing an alert that the channel is not capable of supporting a present channel load and present operating values.

7. The method of claim 1, further comprising the step of transmitting a signal to the electronic module to provide additional cooling thereto.

8. The method of claim 1, further comprising the step of providing an alert that the electronic module is not capable of supporting the plurality of channels without exceeding the worst-case module thermal behavior value.

9. A method for monitoring power consumption of an electronic module having a plurality of channels, the method comprising:
determining whether the electronic module is capable of supporting the plurality of channels without exceeding a worst-case module thermal behavior value;
calculating a power margin value representative of remaining power available in the electronic module to be used by at least one additional channel.

10. The method of claim 9, wherein the step of determining whether the electronic module is capable of supporting the plurality of channels without exceeding the worst-case module thermal behavior value comprises the steps of:
for each channel of the plurality of channels, measuring a present operating value, determining a present channel load value using the present operating value, determining a worst-case channel power dissipation value using the present operating value, and determining a worst-case channel thermal behavior value using the present operating value;
calculating a sum of the present channel load values using each of the measured present channel load values;
calculating a worst-case module power dissipation value using the sum of each of the worst-case channel power dissipation values;
calculating a worst-case module thermal behavior value using the sum of each of the worst-case thermal behavior values; and
calculating the difference between the worst-case module thermal behavior value and the present operating value.

11. A power consumption monitoring apparatus comprising:
an interface comprising an input and an output;
a controller coupled to the interface, the controller configured to determine whether an electric module is capable of supporting a plurality of channels without exceeding a worst-case module thermal behavior value, the controller configured to calculate a power margin value representative of the remaining power available in the electric module to be used by at least one additional channel, the controller configured to transmit a signal to the output of the interface indicating remaining power available in the electric module or a lack of power available in the electric module.

12. The power consumption monitoring apparatus of claim 11, wherein for each channel of the plurality of channels, the controller is further configured to:
measure a present operating value;
determine a present channel load value using the present operating value;
determine a worst-case channel power dissipation value using the present operating value; and
determine a worst-case channel thermal behavior value using the present operating value.

13. The power consumption monitoring apparatus of claim 12, wherein the controller is further configured to:
calculate a sum of the present channel load values using each of the measured present channel load values;
calculate a worst-case module power dissipation value using the sum of each of the worst-case channel power dissipation values;
calculate a worst-case module thermal behavior value using the sum of each of the worst-case thermal behavior values; and
calculate the difference between the worst-case module thermal behavior value and the sum of the present channel load values.

14. The power consumption monitoring apparatus of claim 13, wherein the controller is configured to determine whether the channel exceeds the worst-case channel thermal behavior value, the controller further configured to transmit a signal to the output of the interface indicating the channel exceeds the worst-case channel thermal behavior value.

15. The power consumption monitoring apparatus of claim 13, wherein the controller is configured to determine whether the channel exceeds the worst-case channel thermal behavior value, the controller further configured to transmit a signal to the output of the interface to cause additional cooling to be provided.
